(19) United States
(12) Patent Application Publication
(10) Pub. No.: US 2005/0265006 A1
(43) Pub. Date: Dec. 1, 2005

(54) Multiplexer circuit layout design

(76) Inventor: Edward Thomas Stanley, Milpitas, CA (US)

Correspondence Address: Edward T. Stanley, 322 San Miguel Ct #2, Milpitas, CA, 95035, US

(21) Appl. No.: 11/097,849

(22) Filed: Apr. 4, 2005

Related U.S. Application Data
(60) Provisional application No. 60/571,624, filed on May 17, 2004.

(51) Int. Cl. H05K 1/00

(52) U.S. Cl. 361/748

(57) ABSTRACT

A multiplexer having 2 output channels or some multiple thereof, and a desired number of inputs per channel, with corresponding inputs from each channel physically located in close proximity to each other and having the same physical circuit length.

### CROSS-REFERENCE TO RELATED APPLICATIONS

This application claims the benefit of provisional patent Appl. No. 60/571,624, filed May 17, 2004 by the present inventor.

### FEDERALLY SPONSORED RESEARCH

Not Applicable

### SEQUENCE LISTINGS OR PROGRAM

Not Applicable

### BACKGROUND OF THE INVENTION

1. Field of Invention

This invention relates to the physical circuit layout and organization of a multiplexer used for routing electrical signals.

2. Prior Art

Voltage and frequency measurements of electrical signals are two of the most common types of measurements routinely made in many different industries and areas of engineering.

One method of making these measurements is to connect one lead of the instrument being used to make the measurement to a convenient point, usually a ground point, on the device to be measured, and then to connect the other lead of the instrument to the point of interest on the device.

A common example of this sort of measurement is to see if a multiple output power supply circuit is indeed supplying the specified voltage at each output point. Sometimes, this sort of measurement is called “single-ended”.

Examples, diagrams, photographs and instructions of this style of measurement can be found in hundreds of engineering text books, application notes and instruction manuals dating back over 50 years.

Another method of making these measurements is to connect one lead of the instrument being used to make the measurement to a point of interest on the device to be measured, and then to connect the other lead of the instrument to the other point of interest on the device.

A common example of this sort of measurement is to measure the voltage across a device of some sort, frequently a resistor or thermocouple. Sometimes, this sort of measurement is called “differential”. In this type of measurement, the length of the measurement leads is frequently an issue. Shorter leads are generally better, but ensuring that the leads are as close to being the same length as possible is also quite important, as the length difference can affect measurement accuracy. Also, keeping the leads together and employing known shielding and noise-reduction techniques is quite important.

Examples, diagrams, photographs and instructions of this style of measurement can be found in hundreds of engineering text books, application notes and instruction manuals dating back over 50 years.

Frequently, many measurements of both types must be made over many points, and making the measurements quickly is important. In order to achieve cost savings, and quickly switch between measurement points, one or more multiplexers are used to provide automated connect and disconnect to a series of specified points.

Generically, a multiplexed is a device that connects 1 point to many points on command, usually to only one point at a time.

A simple example is a bank of relays, frequently available commercially in groups of 8 or 16. The common poles of each relay are wired together and thence to an instrument, frequently a digital multimeter. The other lead of the multimeter is connected to a suitable point on the device to be measured. The normally-open poles are then connected by wire to the points to be measured on the device. Closing only one specified relay will allow a desired measurement to be made at the specified point. Opening this relay, then closing another will allow a quick change to another point.

This example is quick and economical, and there are commercial versions available that provide better performance, usually in terms of improved noise immunity, increased bandwidth, etc.

Doing a differential measurement is a bit more involved, as lead length differences are less easily controlled, and shielding and noise-rejection techniques employed are not necessarily those recommended for differential measurements.

There are also instances where doing some single-ended measurements, then doing some differential measurements, in an automated environment, is desirable. Minimizing the amount of required external hardware is of some economic concern.

### BACKGROUND OF THE INVENTION-OBJECTS AND ADVANTAGES

Accordingly, several of the objects and advantages of the present invention are:
(a) a multiplexer that has 2 independent channels, or some multiple thereof, with the corresponding inputs of each channel paired and interleaved on the circuit board;
(b) a multiplexer that has 2 independent channels, or some multiple thereof, with the circuit trace lengths of each input channel pair the same;
(c) a multiplexer that has 2 independent channels, or some multiple thereof, with the relays of each channel controlled independently of each other;

### SUMMARY

In accordance with the present invention a multiplexer having 2 output channels or some multiple thereof, and a desired number of inputs per channel, with corresponding inputs from each channel physically located in close proximity to each other and having the same physical circuit length.

### DRAWINGS

### Figures

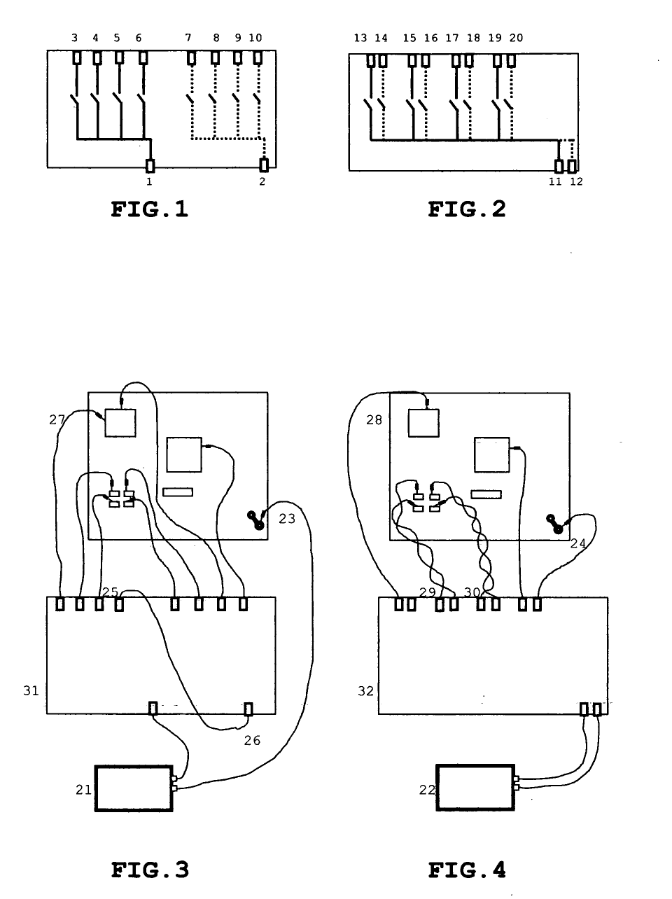

FIG. 1 shows a typical 2-channel multiplexer, each channel configured as a 1-to-4 design. One channel is shown as solid lines, the other as dotted. In this case, the circuits may be on the same layer of the printed circuit board, or they may be on different layers.

FIG. 2 shows the present invention. In this example, the horizontal solid line obscures the dotted horizontal line because the dotted line is on a different board layer.

### REFERENCE NUMERALS

1 Channel 1 output
2 Channel 2 output
3 Channel 1 input 1
4 Channel 1 input 2
5 Channel 1 input 3
6 Channel 1 input 4
7 Channel 2 input 1
8 Channel 2 input 2
9 Channel 2 input 3
10 Channel 2 input 4
11 Channel 1 output
12 Channel 1 output
13 Channel 1 input 1, paired with channel 2 input 1
14 Channel 2 input 1, paired with channel 1 input 1
15 Channel 1 input 2, paired with channel 2 input 2
16 Channel 2 input 2, paired with channel 1 input 2
17 Channel 1 input 3, paired with channel 2 input 3
18 Channel 2 input 3, paired with channel 1 input 3
19 Channel 1 input 4, paired with channel 2 input 4
20 Channel 2 input 4, paired with channel 1 input 4
21 Digital Multimeter
22 Digital Multimeter
23 Printed circuit board electrical round point
24 Printed circuit board electrical round point
25 Equivalent to point 6 in FIG. 1
26 Equivalent to point 2 in FIG. 1
27 A printed circuit board
28 A printed circuit board
29 A differential measurement cable
30 A differential measurement cable
31 A multiplexer, as described in FIG. 1, internal circuitry omitted for clarity
32 A multiplexer, as described in FIG. 2, internal circuitry omitted for clarity

### DESCRIPTION—FIGS.

### FIG. 1—Typical Practice

A typical 2-channel 4-input multiplexer channel layout is shown in FIG. 1. Commercially available multiplexers occur in many forms; 1-channel and 2-channel are common, 4-channel less so. Four inputs per channel is a bit low for most commercial devices, but it makes for a clear diagram. 8, 16 and 32 inputs per channel are more common.

The various external connection points are numbered 1 through 10 and are shown generically, since many possible connection mechanisms may be used. Individual connections, such screw terminals, wire-wrap pins, SMA connectors, among others, are suitable.

The relays for each channel input are shown using the customary engineering notation for a relay.

### FIG. 2 Typical Embodiment

FIG. 2 shows the described channel layout. Effectively, channel 1 input 1 and channel 2 input 1 have been physically located in close proximity to each other, such that the physical length of the circuitry, from input to output is equal. They are effectively paired. This is also true for channel 1 input 2 and channel 2 input 2, and in fact all remaining channel inputs. The length from 11 to 13 is equal to the length from 12 to 14, and this is suitable for making differential measurements. It is relatively unimportant for single-ended measurements. This is also true for 11 to 19 and 12 to 20. The length from 11 to 13 is noticeably longer than from 12 to 20, but a differential measurement is not intended to be made from 13 and 20, as they are not paired.

This design allows either single-ended or differential measurements to be made, depending on the type of cable connected to the inputs in FIG. 2.

For example, single cables could be connected to 13,19 and 20, and appropriate 2-conductor cables connected to 15 and 16 and also to 17 and 18. This allows single-ended measurements to be made form 13,14 and 19, and differential measurements to be made from the 15-16 pair and the 17-18 pair. 14 is not used, as 20, on the same circuit, is connected to ground.

FIG. 4 shows how the previous example could be implemented. The internal circuitry is as FIG. 2, but is omitted here for clarity. Points 29 and 30 indicate, respectively, the 15-16 and 17-18 differential pair of FIG. 2. The wires are shown twisted together, as is common practice.

FIG. 3 shows essentially the same measurements, but using a typical multiplexer. All of the points in FIG. 4 are accessed, and even one additional point, near label 27, by connecting 25 to 26 (see FIGS. 1, 2 & 6). However, all measurements are single-ended. Circuit length and inefficient noise rejection make differential measurements suspect.

The end-user of the multiplexer described in FIG. 2 is able to determine the types of measurement needed, and connect cables accordingly.

Note that in FIG. 2 all of the relays are still independent of each other. Ganged relays could be used on each pair, if the multiplexer is to be dedicated to differential measurements, but the flexibility to choose between single-ended and differential measurements will be lost.

Note that if individual connections for 13-20 are replaced by a multi-pin connector, then a cable may be connected to the multiplexer inputs. The far end of the cable may either stripped and connected directly to probes and used directly, or be connected to another device that provides connection to individual probes. Measurement types than become a matter of determining what connections to use, and ensuring that the cable lengths are still equivalent. This offers considerable additional measurement flexibility, but at the potential risk of reduced measurement accuracy.

1. In a multiplexer with 2 independent channels, or some multiple thereof,
1. The improvement wherein the corresponding inputs of each channel are interleaved and paired on the circuit board;
2. The improvement wherein the circuit trace lengths of each channel input pair are the same.
